(19) United States
(12) Patent Application Publication
(10) Pub. No.: US 2022/0384510 A1
(43) Pub. Date: Dec. 1, 2022

(54) METHOD OF MANUFACTURING LIGHT-RECEIVING DEVICE AND LIGHT-RECEIVING DEVICE

(71) Applicant: Sumitomo Electric Industries, Ltd., Osaka (JP)

(72) Inventor: Masaki MIGITA, Osaka-shi (JP)

(73) Assignee: Sumitomo Electric Industries, Ltd., Osaka (JP)

(21) Appl. No.: 17/695,893

(22) Filed: Mar. 16, 2022

(30) Foreign Application Priority Data
May 27, 2021 (JP) 2021-089179

(51) Int. Cl. H01L 27/146; H01L 23/00

(52) U.S. Cl. CPC H01L 27/14634; H01L 27/1469; H01L 27/14636; H01L 24/81; H01L 24/83; H01L 24/13; H01L 24/16; H01L 2224/81203; H01L 2224/81815; H01L 2224/81143; H01L 2224/83203; H01L 2224/13016; H01L 2224/16057

(57) ABSTRACT

A sensor array and a read-out circuit are prepared. The sensor array and the read-out circuit are aligned such that each first electrode and each second electrode face each other in a state where a connection material is disposed between a second area of the sensor array and a fourth area of the read-out circuit. The read-out circuit is pressed against the sensor array with a first load such that the sensor array and the readout circuit are bonded by the connection material with a gap provided between each first electrode and each second electrode. The read-out circuit is pressed against the sensor array with a second load larger than the first load so that each first electrode and each second electrode are connected. Before the pressing with the second load, either one of the first electrode and the second electrode has a conical shape.

### CROSS REFERENCE TO RELATED APPLICATIONS

This application claims priority based on Japanese Patent Application No. 2021-089179 filed on May 27, 2021, and the entire contents of the Japanese patent application are incorporated herein by reference.

### TECHNICAL FIELD

The present disclosure relates to a method for manufacturing a light-receiving device and a light-receiving device.

### BACKGROUND

Japanese Unexamined Patent Application Publication No. 2017-201664 discloses bar-shaped metal bumps with one side extended in order to connect semiconductor chips each having a different thermal expansion coefficient at a high density.

Naoya Watanabe et al., “Pyramid Bumps for Fine-Pitch Chip-Stack Interconnection” J. Appl. Phys. 44 2751 (2005) discloses a method of connecting two chips to each other using pyramidal bumps.

### SUMMARY

A method of manufacturing a light-receiving device according to an aspect of the present disclosure includes a preparing a sensor array including a first substrate having a first main surface including a first area and a second area surrounding the first area, a plurality of light-receiving elements arranged two-dimensionally in the first area, and a plurality of first electrodes each of which is connected to a corresponding one of the plurality of light-receiving elements, preparing a read-out circuit including a second substrate having a second main surface including a third area and a fourth area surrounding the third area and a plurality of second electrodes arranged two-dimensionally in the third area, aligning the sensor array and the read-out circuit with each other so that each of the plurality of first electrodes and a corresponding one of the plurality of second electrodes face each other in a state in which a connection material is disposed between the second area of the first main surface and the fourth area of the second main surface, pressing, after the aligning, the read-out circuit against the sensor array with a first load so that the sensor array and the read-out circuit are bonded to each other by the connection material in a state in which a gap is provided between each of the plurality of first electrodes and a corresponding one of the plurality of second electrodes, and pressing, after the pressing with the first load, the read-out circuit against the sensor array with a second load greater than the first load so that each of the plurality of first electrodes and a corresponding one of the plurality of second electrodes are connected to each other. Before the pressing with the second load, either one of each of the plurality of first electrodes and each of the plurality of second electrodes has a conical shape.

### BRIEF DESCRIPTION OF THE DRAWINGS

The foregoing and other purposes, aspects and advantages will be better understood from the following detailed description with reference to the drawings.

FIG. 1 is a plan view schematically illustrating a light-receiving device according to an embodiment.

FIG. 2 is a cross-sectional view taken along line II-II of FIG. 1.

FIG. 3 is a cross-sectional view illustrating one step in a method of manufacturing a light-receiving device according to an embodiment.

FIG. 4 is a cross-sectional view illustrating one step in a method of manufacturing a light-receiving device according to an embodiment.

FIG. 5 is a cross-sectional view illustrating one step in a method of manufacturing a light-receiving device according to an embodiment.

FIG. 6 is a cross-sectional view illustrating one step in a method of manufacturing a light-receiving device according to an embodiment.

FIG. 7 is a cross-sectional view schematically illustrating a light-receiving device according to another embodiment.

FIG. 8 is a cross-sectional view schematically illustrating a light-receiving device according to another embodiment.

FIG. 9 is a plan view schematically illustrating a light-receiving device according to another embodiment.

### DETAILED DESCRIPTION

A light-receiving device includes a sensor array and a read-out circuit connected to the sensor array. The sensor array has a plurality of light-receiving elements arranged two-dimensionally.

When manufacturing the light-receiving device, an electrode of each light-receiving element and an electrode of the read-out circuit are connected using a flip-chip bonder. Considering a required load applied to the electrode of one light-receiving element, as the number of light-receiving elements increases, a larger load is required to press the read-out circuit against the sensor array. In this case, since it is difficult to apply a large load using a flip-chip bonder, the large load is applied using a press device having relatively low alignment accuracy.

The present disclosure provides a method of manufacturing a light-receiving device capable of connecting a sensor array and a read-out circuit with high alignment accuracy, and a light-receiving device.

### DESCRIPTION OF EMBODIMENTS OF THE PRESENT DISCLOSURE

A method of manufacturing a light-receiving device according to an embodiment includes preparing a sensor array including a first substrate having a first main surface including a first area and a second area surrounding the first area, a plurality of light-receiving elements arranged two-dimensionally in the first area, and a plurality of first electrodes each of which is connected to a corresponding one of the plurality of light-receiving elements; preparing a read-out circuit including a second substrate having a second main surface including a third area and a fourth area surrounding the third area and a plurality of second electrodes arranged two-dimensionally in the third area; aligning the sensor array and the read-out circuit with each other so that each of the plurality of first electrodes and a corresponding one of the plurality of second electrodes face each other in a state in which a connection material is disposed between the second area of the first main surface and the fourth area of the second main surface; pressing, after the aligning, the read-out circuit against the sensor array with a first load so that the sensor array and the read-out circuit are bonded to each other by the connection material in a state in which a gap is provided between each of the plurality of first electrodes and a corresponding one of the plurality of second electrodes; and pressing, after the pressing with the first load, the read-out circuit against the sensor array with a second load greater than the first load so that each of the plurality of first electrodes and a corresponding one of the plurality of second electrodes are connected to each other. Before the pressing with the second load, either one of each of the plurality of first electrodes and each of the plurality of second electrodes has a conical shape.

According to the above-described method of manufacturing the light-receiving device, the sensor array and the read-out circuit can be temporarily fixed by the connection material in a state where the sensor array and the read-out circuit are aligned with high alignment accuracy. Therefore, misalignment between the sensor array and the read-out circuit are suppressed before the pressing step being performed with the second load. Therefore, the sensor array and the read-out circuit can be connected with high alignment accuracy.

The connection material may include a solder. In this case, the sensor array and the read-out circuit can be temporarily fixed by the solder.

The method of manufacturing may further include heating the connection material so as to melt the solder, between the pressing with the first load and the pressing with the second load. In this case, when the solder is melted, alignment accuracy between the sensor array and the read-out circuit is further improved due to self-alignment.

The connection material may include a thermosetting resin. In this case, the sensor array and the read-out circuit can be temporarily fixed by the thermosetting resin.

The first main surface may have a rectangular shape, and, in the aligning, the connection material may be located at a corner of the first main surface as seen from a direction perpendicular to the first main surface. In this case, higher alignment accuracy can be obtained as compared with the case where the connection material is located at a side portion of the first main surface.

In the aligning, the connection material may have, in a direction along the first main surface, a third diameter greater than a first diameter of each of the plurality of first electrodes and a second diameter of each of the plurality of second electrodes. In this case, since a connection area between the connection material and the sensor array and a connection area between the connection material and the read-out circuit are increased, the sensor array and the read-out circuit can be firmly connected.

A light-receiving device according to an embodiment includes a sensor array including a first substrate having a first main surface including a first area and a second area surrounding the first area, a plurality of light-receiving elements arranged two-dimensionally in the first area, and a plurality of first electrodes each of which is connected to a corresponding one of the plurality of light-receiving elements; a read-out circuit including a second substrate having a second main surface including a third area and a fourth area surrounding the third area and a plurality of second electrodes arranged two-dimensionally in the third area; and a connection member that connects the second area of the first main surface and the fourth area of the second main surface to each other. Each of the plurality of first electrodes and a corresponding one of the plurality of second electrodes are connected to each other. Either one of each of the plurality of first electrodes and each of the plurality of second electrodes has a frustum shape.

According to the above-described light-receiving device, the sensor array and the read-out circuit are connected with high alignment accuracy by the connection member.

The connection member may include a solder. In this case, the sensor array and the read-out circuit are connected by the solder.

The connection member may include a thermosetting resin. In this case, the sensor array and the read-out circuit are connected by the thermosetting resin.

The first main surface may have a rectangular shape and the connection member may be located at a corner of the first main surface as seen from a direction perpendicular to the first main surface. In this case, higher alignment accuracy can be obtained as compared with the case where the connection member is located at a side portion of the first main surface.

The connection member may have, in a direction along the first main surface, a third diameter greater than a first diameter of each of the plurality of first electrodes and a second diameter of each of the plurality of second electrodes. In this case, since a connection area between the connection member and the sensor array and a connection area between the connection member and the read-out circuit are increased, the sensor array and the read-out circuit can be firmly connected.

### Details of Embodiments of the Present Disclosure

Hereinafter, embodiments of the present disclosure will be described in detail with reference to the accompanying drawings. In the description of the drawings, the same reference numerals are used for the same or equivalent elements, and redundant description is omitted. In the drawings, an X-axis direction, a Y-axis direction, and a Z-axis direction that intersect each other are shown. The X-axis direction, the Y-axis direction, and the Z-axis direction are orthogonal to each other, for example.

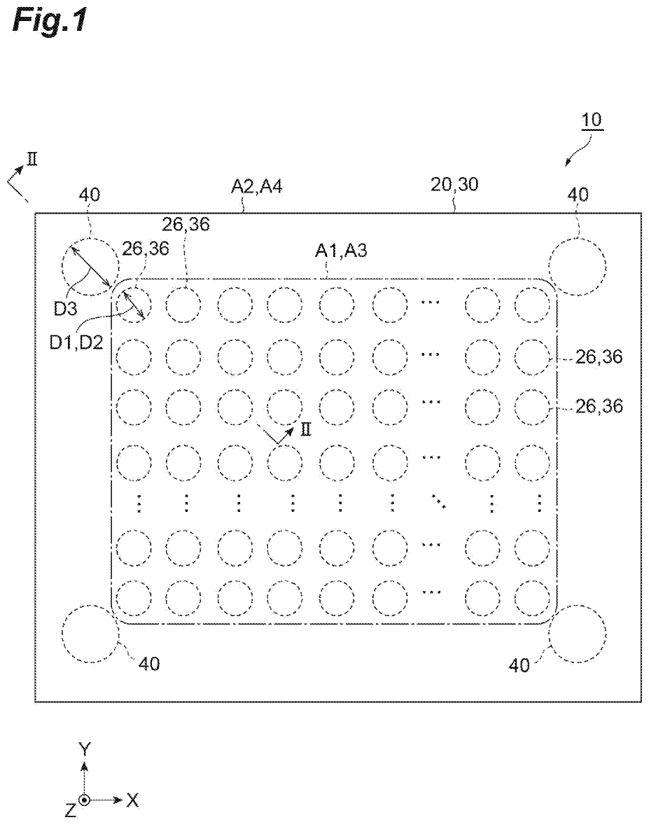

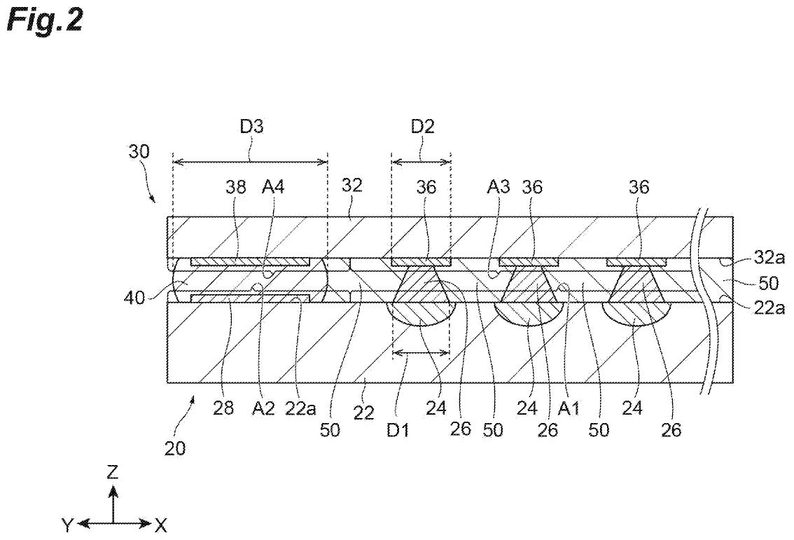

FIG. 1 is a plan view schematically illustrating a light-receiving device according to an embodiment. FIG. 2 is a cross-sectional view taken along line II-II of FIG. 1. A light-receiving device 10 shown in FIGS. 1 and 2 is, for example, an infrared image sensor. Light-receiving device 10 includes a sensor array 20 and a read-out circuit 30. Sensor array 20 can convert light incident on light-receiving device 10 into an electrical signal. Read-out circuit 30 can read out the electrical signal generated in sensor array 20.

Sensor array 20 includes a first substrate 22, a plurality of light-receiving elements 24, and a plurality of first electrodes 26. First substrate 22 has a first main surface 22a including a first area A1 and a second area A2. First main surface 22a may have a rectangular shape. Second area A2 surrounds first area A1. First substrate 22 may be a group III-V compound semiconductor substrate such as an InP substrate.

The plurality of light-receiving elements 24 are arranged two dimensionally in first area A1. The plurality of light-receiving elements 24 are arranged in an array, for example, in the X-axis direction and the Y-axis direction. Each light-receiving element 24 may be, for example, a semiconductor light-receiving element such as a photodiode. Each light-receiving element 24 corresponds to one pixel.

The plurality of first electrodes 26 are respectively connected to the plurality of light-receiving elements 24. Each first electrode 26 is provided on each light-receiving element 24. Thus, the plurality of first electrodes 26 are arranged two dimensionally in first area A1. Each first electrode 26 may have a frustum shape, such as a frustum of a pyramid or a frustum of a cone. Each first electrode 26 may have a diameter that decreases with distance from each light-receiving element 24 in the Z-axis direction. Each first electrode 26 may be a metal bump including, for example, gold or copper. A third electrode 28 may be provided on second area A2. Third electrode 28 may be an electrode having a flat surface. Third electrode 28 may include the same material as that included in first electrode 26.

Read-out circuit 30 includes a second substrate 32 and a plurality of second electrodes 36. Second substrate 32 has a second main surface 32a that includes a third area A3 and a fourth area A4. Fourth area A4 surrounds third area A3. Second main surface 32a may have a rectangular shape. Second substrate 32 may be a semiconductor substrate such as a silicon substrate, for example.

The plurality of second electrodes 36 are arranged two dimensionally in third area A3. The plurality of second electrodes 36 are arranged in an array, for example, in the X-axis direction and the Y-axis direction. As seen from the Z-axis direction, each second electrode 36 may at least partially overlap each first electrode 26. Each second electrode 36 may have a flat surface, for example. Each second electrode 36 may be a metal electrode including, for example, gold, copper, or the like. Each first electrode 26 and each second electrode 36 are connected to each other. Atop surface of each first electrode 26 and the surface of each second electrode 36 may be bonded. Thus, each light-receiving element 24 of sensor array 20 is electrically connected to read-out circuit 30. A fourth electrode 38 may be provided on fourth area A4. Fourth electrode 38 may be an electrode having a flat surface. Fourth electrode 38 may include the same material as that included in second electrode 36.

Light-receiving device 10 includes a connection member 40 that connects second area A2 of first main surface 22a and fourth area A4 of second main surface 32a. Third electrode 28 may be disposed between connection member 40 and second area A2. Fourth electrode 38 may be disposed between connection member 40 and fourth area A4. In this embodiment, connection member 40 includes, for example, a solder. The solder may contain indium. Connection member 40 may be located at a corner of first main surface 22a as seen from a direction (the Z-axis direction) orthogonal to first main surface 22a. Specifically, when first main surface 22a has a rectangular shape, connection members 40 are disposed inside the corners of the rectangle as seen from the Z-axis direction so as to face the corners of first main surface 22a. Connection member 40 may be disposed at each of four corners of first main surface 22a. Connection member 40 has, for example, a cylindrical shape extending in the Z-axis direction. Connection member 40 may have a third diameter D3 larger than a first diameter D1 of each first electrode 26 and a second diameter D2 of each second electrode 36 in a direction along first main surface 22a (a direction orthogonal to the Z-axis direction). First diameter D1 may be a maximum value of the diameter of each first electrode 26 in a direction along first main surface 22a. Second diameter D2 may be a maximum value of the diameter of each second electrode 36 in a direction along first main surface 22a. Second diameter D2 may be the same as first diameter D1. Third diameter D3 may be a maximum value of the diameter of connection members 40 in a direction along first main surface 22a. Connection member 40 may be a conductive member that connects third electrode 28 and fourth electrode 38. In this case, sensor array 20 and read-out circuit 30 can be electrically connected by connection member 40.

Light-receiving device 10 may include a resin member 50 provided between first main surface 22a and second main surface 32a. Resin member 50 functions as an underfill. Resin member 50 may include, for example, an epoxy resin. Resin member 50 improves a mechanical strength of light-receiving device 10.

According to light-receiving device 10 of this embodiment, sensor array 20 and read-out circuit 30 are connected by connection member 40 with high alignment accuracy (alignment accuracy in the X-axis direction and the Y-axis direction). Thus, a large number of light-receiving elements 24 can be arranged at a narrow pitch.

When connection member 40 is located at the corner of first main surface 22a, higher alignment accuracy is obtained than when connection member 40 is located at a side portion of first main surface 22a.

When connection member 40 has large third diameter D3, since the connection area between connection member 40 and sensor array 20 and the connection area between connection member 40 and read-out circuit 30 are increased, sensor array 20 and read-out circuit 30 can be firmly connected.

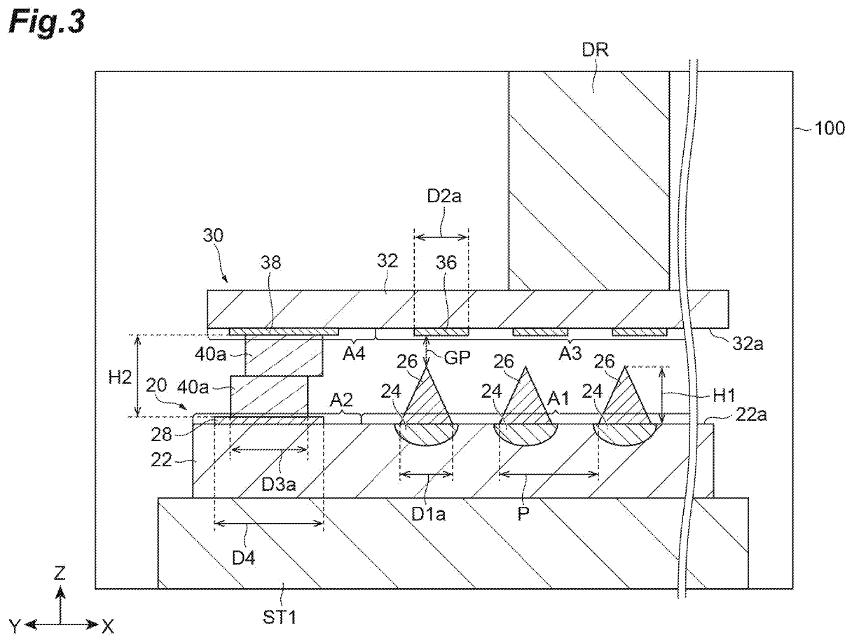

FIGS. 3 to 6 are cross-sectional views each illustrating one step in a method of manufacturing the light-receiving device according to the embodiment. Light-receiving device 10 can be manufactured by the following method.

(Preparation Step)

First, as shown in FIG. 3, sensor array 20 and read-out circuit 30 are prepared. In this step, each first electrode 26 may have a conical shape, such as a pyramid or a cone. A plurality of connection materials 40a for forming one connection member 40 may be disposed both on third electrode 28 of sensor array 20 and on fourth electrode 38 of read-out circuit 30, respectively. Each connection material 40a may include a solder. Connection material 40a may be disposed on only one of third electrode 28 of sensor array 20 and fourth electrode 38 of read-out circuit 30. Connection material 40a has, for example, a cylindrical shape extending in the Z-axis direction.

(Alignment Step)

Next, as shown in FIG. 3, with connection materials 40a disposed between second area A2 of first main surface 22a and fourth area A4 of second main surface 32a, sensor array 20 and read-out circuit 30 are aligned so that each first electrode 26 and each second electrode 36 face each other. A gap GP is provided between each first electrode 26 and each second electrode 36. This step may be performed using a flip-chip bonder 100. More specifically, after read-out circuit 30 is placed on a stage ST1 of flip-chip bonder 100, sensor array 20 is driven along a direction (the X-axis direction and/or the Y-axis direction) along first main surface 22a using a drive unit DR of flip-chip bonder 100.

In this step, connection material 40a may be located at a corner of first main surface 22a as seen from the Z-axis direction. Connection material 40a may be disposed at each of four corners of first main surface 22a. Connection material 40a may have a third diameter D3a greater than a first diameter D1a of each first electrode 26 and a second diameter D2a of each second electrode 36 in the direction along first main surface 22a. Second diameter D2a may be the same as first diameter D1a. Third diameter D3a of connection material 40a is smaller than third diameter D3 of connection member 40 shown in FIGS. 1 and 2. Third electrode 28 may have a diameter D4 greater than third diameter D3a of connection material 40a in the direction along first main surface 22a. In the direction along first main surface 22a, first electrodes 26 are arranged in an array at a pitch P. Pitch P may be 30 μm or less.

First diameter D1a and a height H1 of each first electrode 26 may be approximately half of pitch P. A total height H2 of the two connection materials 40a is the same as a distance between third electrode 28 and fourth electrode 38. Third diameter D3a and total height H2 of connection materials 40a may be of the same as pitch P. A difference between diameter D4 of third electrode 28 and third diameter D3a of connection material 40a may be about 1/10 of pitch P.

In a first example in which pitch P is 30 μm, first diameter D1a and height H1 of first electrode 26 are, for example, from 10 μm to 20 μm. Third diameter D3a and total height H2 of connection materials 40a are, for example, from 25 μm to 35 μm. The difference between diameter D4 of third electrode 28 and third diameter D3a of connection material 40a is, for example, from 28 μm to 38 μm.

In a second example in which pitch P is 15 μm, first diameter D1a and height H1 of first electrode 26 are, for example, from 5 μm to 10 μm. Third diameter D3a and total height H2 of connection materials 40a are, for example, from 12 μm to 18 μm. The difference between diameter D4 of third electrode 28 and third diameter D3a of connection material 40a is, for example, from 14 μm to 20 μm.

In a third example in which pitch P is 10 μm, first diameter D1a and height H1 of first electrode 26 are, for example, from 4 μm to 6 μm. Third diameter D3a and total height H2 of connection materials 40a are, for example, from 9 m to 11 am. The difference between diameter D4 of third electrode 28 and third diameter D3a of connection material 40a is, for example, from 10 μm to 12 μm.

(First Pressing Step)

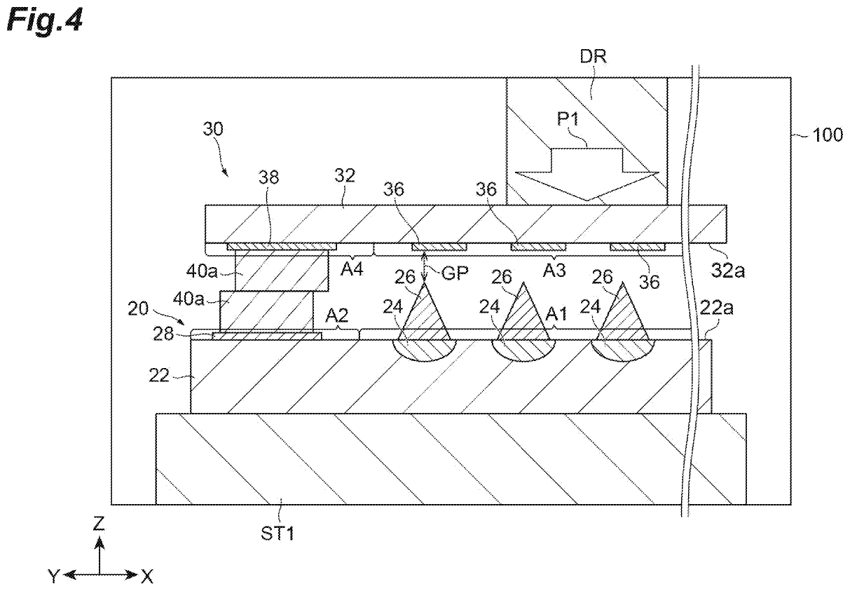

Next, as shown in FIG. 4, with gap GP provided between each first electrode 26 and each second electrode 36, read-out circuit 30 is pressed against sensor array 20 with a first load P1 so that sensor array 20 and read-out circuit 30 are connected by connection material 40a. As a result, read-out circuit 30 is temporarily bonded to sensor array 20. As a result, read-out circuit 30 and sensor array 20 are temporarily fixed. First load P1 may be greater than 0 N and less than or equal to 20 N. This step may be performed using flip-chip bonder 100. When this step is performed using flip-chip bonder 100, first load P1 is applied to read-out circuit 30 by drive unit DR. After completion of this step, the temporarily fixed sensor array 20 and read-out circuit 30 are taken out from flip-chip bonder 100.

(Reflow Step)

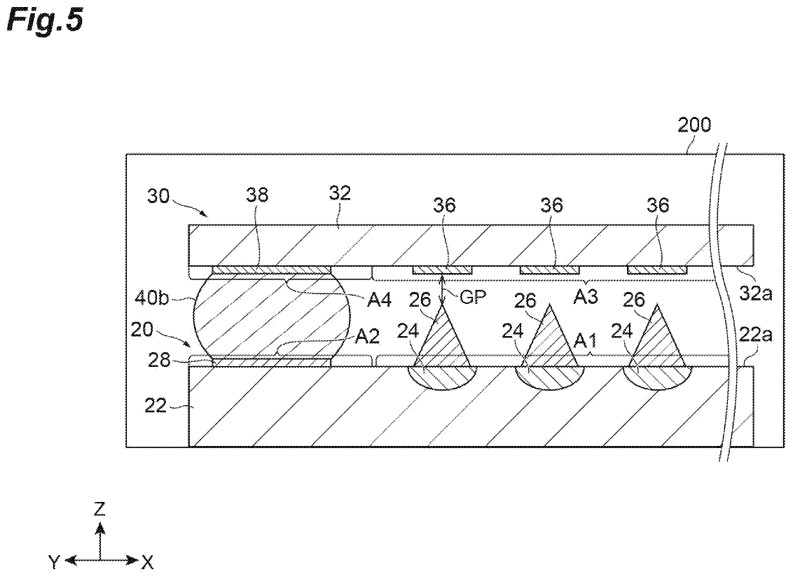

Next, when connection material 40a includes the solder, as shown in FIG. 5, connection material 40a may be heated so as to melt the solder. Also in this step, gap GP is provided between each first electrode 26 and each second electrode 36. A heating temperature is higher than a melting point of the solder (for example, 157° C.). When connection material 40a is melted by heating and changed into a connection material 40b which is liquid, read-out circuit 30 moves relative to sensor array 20 in the direction along first main surface 22a due to surface tension. As a result, sensor array 20 and read-out circuit 30 are self-aligned. Thereafter, connection material 40b is cooled and solidified. This step may be performed using a reflow device 200. After completion of this step, sensor array 20 and read-out circuit 30 are taken out from reflow device 200.

(Second Pressing Step)

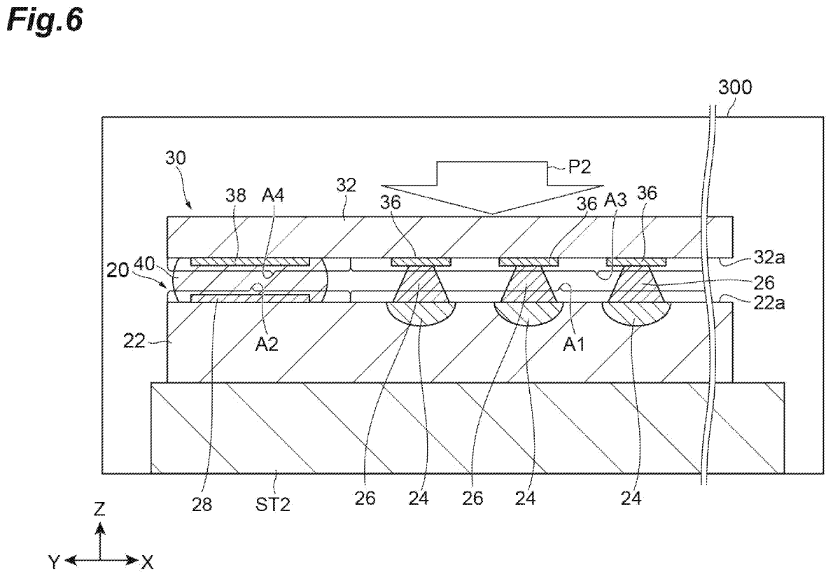

Next, as shown in FIG. 6, read-out circuit 30 is pressed against sensor array 20 with a second load P2 so that each first electrode 26 and each second electrode 36 are connected to each other. Second load P2 is greater than first load P1. Second load P2 may be 50 N or greater. In this step, a tip of each first electrode 26 is deformed by a surface of each second electrode 36. Thus, each first electrode 26 having a frustum shape such as a frustum of pyramid or a frustum of cone is formed. Further, connection material 40b is deformed to form connection member 40. In this step, sensor array 20 and read-out circuit 30 may be heated. As a result, a bonding strength between each first electrode 26 and each second electrode 36 is improved, and an electrical resistance between each first electrode 26 and each second electrode 36 is reduced. A heating temperature is lower than the melting point of connection material 40a. This step may be performed by using a pressing device different from the pressing device used in the first pressing step. For example, this step may be performed using a press device 300. More specifically, after sensor array 20 and read-out circuit 30 are placed on a stage ST2 of press device 300, read-out circuit 30 is pressed onto sensor array 20 by second load P2. Press device 300 may have a lower alignment accuracy compared to flip-chip bonder 100 or may not have an alignment function itself. Press device 300 can apply a large load compared to flip-chip bonder 100 (for example, 10 kN or more) to read-out circuit 30.

(Resin Member Forming Step)

Next, as shown in FIG. 2, resin member 50 may be formed between first main surface 22a and second main surface 32a. After a liquid resin is disposed between first main surface 22a and second main surface 32a using capillary action, the liquid resin may be heated and cured. After the liquid resin is disposed between first main surface 22a and second main surface 32a between the reflow step and the second pressing step, the liquid resin may be heated and cured. In this case, the liquid resin may be cured by heating in the second pressing step.

According to the manufacturing method of this embodiment, sensor array 20 and read-out circuit 30 can be temporarily fixed by connection material 40a in a state which sensor array 20 and read-out circuit 30 are aligned with high alignment accuracy. Therefore, for example, even if sensor array 20 and read-out circuit 30 are transported before the subsequent second pressing step is performed, positional shift between sensor array 20 and read-out circuit 30 is less likely to occur. Therefore, sensor array 20 and read-out circuit 30 can be connected with high alignment accuracy.

When the reflow process is performed, the alignment accuracy between sensor array 20 and read-out circuit 30 is further improved due to self-alignment when the solder is melted. Therefore, it is possible to connect sensor array 20 and read-out circuit 30 with higher alignment accuracy.

When connection materials 40a are located at the corners of first main surface 22a as seen from the Z-axis direction, higher alignment accuracy is obtained compared to a case where connection material 40a is located at the side portion of first main surface 22a.

When connection material 40a has the large third diameter D3a, since the connection area between connection material 40a and sensor array 20 and the connection area between connection material 40a and read-out circuit 30 are increased, sensor array 20 and read-out circuit 30 can be firmly connected.

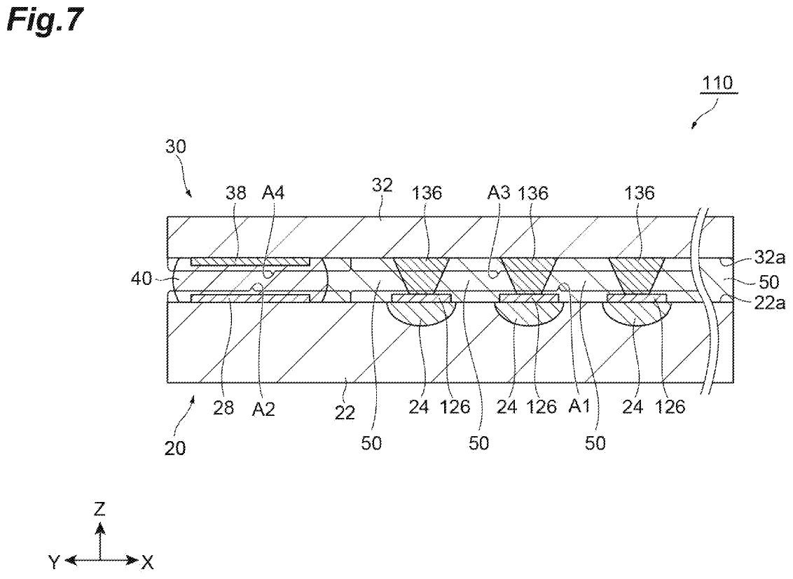

FIG. 7 is a cross-sectional view schematically illustrating a light-receiving device according to another embodiment. A light-receiving device 110 shown in FIG. 7 has the same configuration as light-receiving device 10 shown in FIGS. 1 and 2, except that shapes of first electrode 26 and second electrode 36 are replaced. Thus, in light-receiving device 110, each first electrode 126 of sensor array 20 has a flat surface, and each second electrode 136 of read-out circuit 30 has a frustum shape, such as a frustum of a pyramid or a frustum of a cone. Also in this embodiment, the same effects as those of light-receiving device 10 can be obtained. Light-receiving device 110 may be manufactured in the same manner as light-receiving device 10.

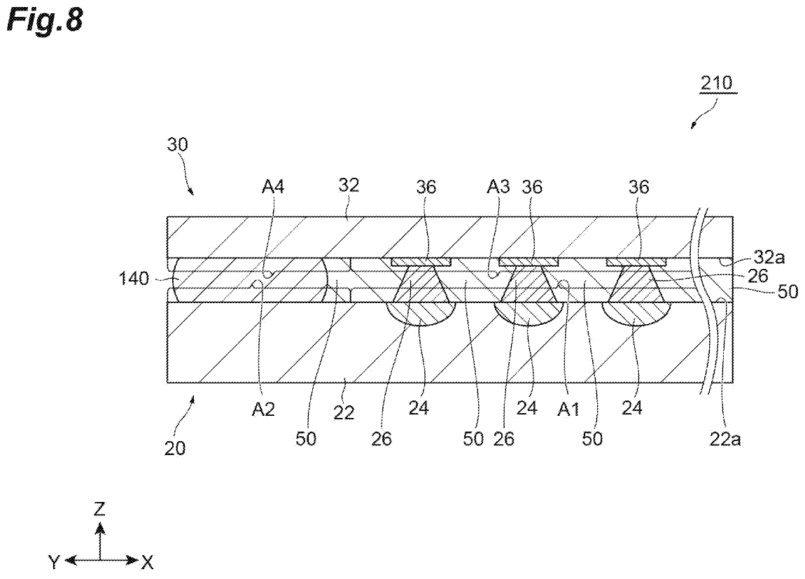

FIG. 8 is a cross-sectional view schematically illustrating a light-receiving device according to another embodiment. A light-receiving device 210 shown in FIG. 8 has the same configuration as light-receiving device 10 shown in FIGS. 1 and 2, except that a connection member 140 is provided instead of connection member 40, and third electrode 28 and fourth electrode 38 are not provided. Connection member 140 includes a thermosetting resin. Connection member 140 may be a resin member including a non-conductive resin such as an epoxy resin, for example, or may be an anisotropic conductive film or a non-conductive film. Also in this embodiment, the same effects as those of light-receiving device 10 can be obtained. In light-receiving device 210, sensor array 20 and read-out circuit 30 are connected by a thermosetting resin. Light-receiving device 210 may be manufactured in the same manner as light-receiving device 10. Light-receiving device 210 may include third electrode 28 and fourth electrode 38. In this case, connection member 140 is disposed between third electrode 28 and fourth electrode 38.

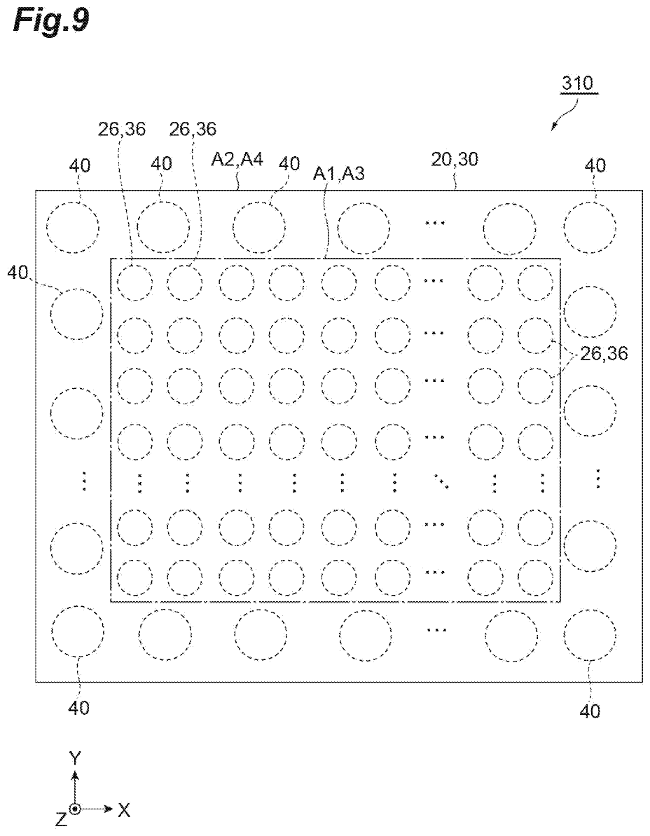

FIG. 9 is a plan view schematically illustrating a light-receiving device according to another embodiment. A light-receiving device 310 shown in FIG. 9 has the same configuration as that of light-receiving device 10 shown in FIGS. 1 and 2, except that it includes additional connection members 40. In light-receiving device 310, as seen from the Z-axis direction, in addition to connection members 40 disposed at each of the four corners of first main surface 22a having a rectangular shape, connection members 40 are also disposed between adjacent corners. A plurality of connection members 40 are disposed along four sides of first main surface 22a. In this embodiment, higher alignment accuracy can be obtained in addition to the same effects as those of light-receiving device 10. Light-receiving device 310 may be manufactured in the same manner as light-receiving device 10.

Although the preferred embodiments of the present disclosure have been described in detail above, the present disclosure is not limited to the above embodiments. The constituent elements of the embodiments may be arbitrarily combined.

It should be understood that the embodiments disclosed herein are illustrative and non-restrictive in every respect. The scope of the present invention is defined by the claims rather than the meaning described above, and is intended to include all modifications within the meaning and scope equivalent to the claims.

What is claimed is:

1. A method of manufacturing a light-receiving device, comprising:
preparing a sensor array including a first substrate having a first main surface including a first area and a second area surrounding the first area, a plurality of light-receiving elements arranged two-dimensionally in the first area, and a plurality of first electrodes each of which is connected to a corresponding one of the plurality of light-receiving elements;
preparing a read-out circuit including a second substrate having a second main surface including a third area and a fourth area surrounding the third area and a plurality of second electrodes arranged two-dimensionally in the third area;
aligning the sensor array and the read-out circuit with each other so that each of the plurality of first electrodes and a corresponding one of the plurality of second electrodes face each other in a state in which a connection material is disposed between the second area of the first main surface and the fourth area of the second main surface;
pressing, after the aligning, the read-out circuit against the sensor array with a first load so that the sensor array and the read-out circuit are bonded to each other by the connection material in a state in which a gap is provided between each of the plurality of first electrodes and a corresponding one of the plurality of second electrodes; and
pressing, after the pressing with the first load, the read-out circuit against the sensor array with a second load greater than the first load so that each of the plurality of first electrodes and a corresponding one of the plurality of second electrodes are connected to each other,
wherein, before the pressing with the second load, either one of each of the plurality of first electrodes and each of the plurality of second electrodes has a conical shape.

2. The method according to claim 1, wherein the connection material includes a solder.

3. The method according to claim 2, further comprising heating the connection material so as to melt the solder, between the pressing with the first load and the pressing with the second load.

4. The method according to claim 1, wherein the connection material includes a thermosetting resin.

5. The method according to claim 1,
wherein the first main surface has a rectangular shape, and
wherein, in the aligning, the connection material is located at a corner of the first main surface as seen from a direction perpendicular to the first main surface.

6. The method according to claim 1, wherein, in the aligning, the connection material has, in a direction along the first main surface, a third diameter greater than a first diameter of each of the plurality of first electrodes and a second diameter of each of the plurality of second electrodes.

7. The method according to claim 1, wherein the pressing with the first load is performed by using a first pressing device, wherein the pressing with the second load is performed by using a second pressing device different from the first pressing device.

8. The method according to claim 1, wherein the first load is greater than 0 N and less than or equal to 20 N.

9. The method according to claim 1, wherein the second load is 50 N or greater.

10. The method according to claim 1, wherein the sensor array and the read-out circuit are heated in the pressing with the second load.

11. The method according to claim 10, a heating temperature in the pressing with the second load is lower than a melting point of the connection material.

12. The method according to claim 1, the connection material is disposed between a third electrode on the second area and a fourth electrode on the fourth area in the aligning.

13. The method according to claim 1, the connection material has a cylindrical shape extending in a direction perpendicular to the first main surface in the aligning.

14. Alight-receiving device comprising:
a sensor array including a first substrate having a first main surface including a first area and a second area surrounding the first area, a plurality of light-receiving elements arranged two-dimensionally in the first area, and a plurality of first electrodes each of which is connected to a corresponding one of the plurality of light-receiving elements;
a read-out circuit including a second substrate having a second main surface including a third area and a fourth area surrounding the third area and a plurality of second electrodes arranged two-dimensionally in the third area; and
a connection member that connects the second area of the first main surface and the fourth area of the second main surface to each other,
wherein each of the plurality of first electrodes and a corresponding one of the plurality of second electrodes are connected to each other, and
wherein either one of each of the plurality of first electrodes and each of the plurality of second electrodes has a frustum shape.

15. The light-receiving device according to claim 14, wherein the connection member includes a solder.

16. The light-receiving device according to claim 14, wherein the connection member includes a thermosetting resin.

17. The light-receiving device according to claim 14,
wherein the first main surface has a rectangular shape, and
wherein the connection member is located at a corner of the first main surface as seen from a direction perpendicular to the first main surface.

18. The light-receiving device according to claim 14, wherein the connection member has, in a direction along the first main surface, a third diameter greater than a first diameter of each of the plurality of first electrodes and a second diameter of each of the plurality of second electrodes.

19. The light-receiving device according to claim 14, wherein the connection member connects a third electrode on the second area and a fourth electrode on the fourth area to each other.
